(19) United States
(12) Patent Application Publication
(10) Pub. No.: US 2021/0398959 A1
(43) Pub. Date: Dec. 23, 2021

(54) DISPLAY PANEL, MANUFACTURING METHOD THEREOF, AND DISPLAY DEVICE

(71) Applicant: Shenzhen China Star Optoelectronics Semiconductor Display Technology Co., Ltd., Shenzhen (CN)

(72) Inventor: Jing GENG, Shenzhen (CN)

(73) Assignee: Shenzhen China Star Optoelectronics Semiconductor Display Technology Co., Ltd., Shenzhen (CN)

(21) Appl. No.: 16/645,797

(22) PCT Filed: Feb. 25, 2020
(86) PCT No.: PCT/CN2020/076535

§ 371 Date: Mar. 10, 2020

(30) Foreign Application Priority Data
Jan. 17, 2020 (CN) 202010052489.2

(51) Int. Cl. H01L 25/16

(52) U.S. Cl. CPC H01L 25/167

(57) ABSTRACT

The present application provides a display panel, a manufacturing method thereof, and a display device. The display panel includes a first glass substrate, a thin-film transistor layer disposed on the first glass substrate, black matrices disposed on the thin-film transistor layer and arranged in an array, first color micro light-emitting diodes (LEDs) disposed on the thin-film transistor layer and disposed between the black matrices, a pixel layer disposed on the first color micro LEDs, and a second glass substrate disposed on the black matrices and the pixel layer.

### FIELD OF APPLICATION

The present application is related to the field of display technology, and specifically to a display panel, a manufacturing method thereof, and a display device.

### BACKGROUND OF APPLICATION

Micro light-emitting diodes (LEDs) refer to thinning, miniaturizing, and arraying LED structure designs. A size of each micro LED is only about 1 to 100 microns. Micro LEDs, like organic light-emitting diodes (OLEDs), are self-luminous and do not need a backlight source. Moreover, micro LEDs have higher efficiency and are thus more energy-efficient than the OLEDs, and have a longer light-emitting life and higher brightness. At the same time, they have many advantages such as ultra-high pixel count, ultra-high resolution, and seamless splice.

In display panels of the prior art, after transferring micro LED chips on thin-film transistor (TFT) substrates, color filter layers are formed thereon. Color filter layers need to be formed with black retaining walls or black matrices by a yellow light process to prevent crosstalk between sub-pixels. High temperature and alkaline developer in the yellow light process affect the micro LEDs and make them fail, thereby affecting overall display effects. Therefore, it is necessary to resolve this defect.

### SUMMARY OF APPLICATION

In display panels of the prior art, micro light-emitting diodes (LEDs) fail because high temperature and alkaline developer in a yellow light process affect the micro LEDs when black matrices are formed on the micro LEDs. As a result, there is a technical problem that affects overall display effects of the display panels.

In order to solve the above problem, the present application provide technical solutions as follows.

A display panel provided by an embodiment of the present application includes a first glass substrate, a thin-film transistor layer, black matrices, first color micro LEDs, a pixel layer, and a second glass substrate. The thin-film transistor layer is disposed on the first glass substrate. The black matrices are disposed on the thin-film transistor layer and are arranged in an array. The first color micro LEDs are disposed on the thin-film transistor layer and are disposed between the black matrices. A height of each of the first color micro LEDs is less than a height of each of the black matrices. The pixel layer is disposed on the first color micro LEDs and includes second color sub-pixels and third color sub-pixels. The second glass substrate is disposed on the black matrices and the pixel layer.

In the display panel provided by an embodiment of the present application, the first color micro LEDs consist of blue micro LEDs, and the second color sub-pixels and the third color sub-pixels respectively consist of red sub-pixels and green sub-pixels.

In the display panel provided by an embodiment of the present application, each of the red sub-pixels and each of the green sub-pixels constitute a repeating unit, and repeating units are cyclically arranged at a pitch of a width of a sub-pixel.

In the display panel provided by an embodiment of the present application, the red sub-pixels and the green sub-pixels are respectively made of a red quantum dot material and a green quantum dot material.

In the display panel provided by an embodiment of the present application, a thickness of each of the black matrices ranges from 10 to 12 microns.

In the display panel provided by an embodiment of the present application, a thickness of the pixel layer ranges from 5 to 7 microns.

A manufacturing method of the display panel provided by an embodiment of the present application includes the steps of: forming a thin-film transistor layer on a first glass substrate; forming black matrices on the thin-film transistor layer, wherein the black matrices are arranged in an array; forming first color micro light-emitting diodes (LEDs) on the thin-film transistor layer, wherein the first color micro LEDs are formed between the black matrices, and a height of each of the first color micro LEDs is less than a height of each of the black matrices; forming a pixel layer on the first color micro LEDs, wherein the pixel layer includes second color sub-pixels and third color sub-pixels; and packaging a second glass substrate on the black matrices and the pixel layer.

In the manufacturing method of the display panel provided by an embodiment of the present application, the first color micro LEDs consist of blue micro LEDs, and the second color sub-pixels and the third color sub-pixels respectively consist of red sub-pixels and green sub-pixels.

In the manufacturing method of the display panel provided by an embodiment of the present application, the red sub-pixels and the green sub-pixels are respectively made of a red quantum dot material and a green quantum dot material.

In the manufacturing method of the display panel provided by an embodiment of the present application, a thickness of each of the black matrices ranges from 10 to 12 microns.

In the manufacturing method of the display panel provided by an embodiment of the present application, a thickness of the pixel layer ranges from 5 to 7 microns.

A display device provided by an embodiment of the present application includes a driving chip and a display panel. The display panel includes a first glass substrate, a thin-film transistor layer, black matrices, first color micro LEDs, a pixel layer, and a second glass substrate. The thin-film transistor layer is disposed on the first glass substrate. The black matrices are disposed on the thin-film transistor layer and are arranged in an array. The first color micro LEDs are disposed on the thin-film transistor layer and are disposed between the black matrices. A height of each of the first color micro LEDs is less than a height of each of the black matrices. The pixel layer is disposed on the first color micro LEDs and includes second color sub-pixels and third color sub-pixels. The second glass substrate disposed on the black matrices and the pixel layer.

In the display device provided by an embodiment of the present application, the first color micro LEDs consist of blue micro LEDs, and the second color sub-pixels and the third color sub-pixels respectively consist of red sub-pixels and green sub-pixels.

In the display device provided by an embodiment of the present application, each of the red sub-pixels and each of the green sub-pixels constitute a repeating unit, and repeating units are cyclically arranged at a pitch of a width of a sub-pixel.

In the display device provided by an embodiment of the present application, the red sub-pixels and the green sub-pixels are respectively made of a red quantum dot material and a green quantum dot material.

In the display device provided by an embodiment of the present application, a thickness of each of the black matrices ranges from 10 to 12 microns.

In the display device provided by an embodiment of the present application, a thickness of the pixel layer ranges from 5 to 7 microns.

Compared to the prior art, the display panel provided by an embodiment of the present application disposes the black matrices as a barrier between adjacent micro LEDs and adjacent sub-pixels. The black matrices with thick film thickness can be configured as black matrices on two sides of the micro LEDs, which block light from a side of the micro LEDs and prevent light between different micro LEDs from crosstalking. Moreover, they can be configured as a pixel defining layer of the pixel layer, restricting a printing region and forming shapes of the sub-pixels at a same time, while preventing different sub-pixels from crosstalking. This not only simplifies manufacturing processes, but also greatly improves contrast of the display panel.

### DESCRIPTION OF DRAWINGS

FIG. 1 is a structural diagram of a display panel provided by an embodiment of the present application.

FIG. 2 is a flowchart of a manufacturing method of the display panel provided by an embodiment of the present application.

FIGS. 3a to 3e are structural diagrams of manufacturing processes of the display panel provided by an embodiment of the present application.

### DETAILED DESCRIPTION OF PREFERRED EMBODIMENTS

The present application provides a display panel, a manufacturing method thereof, and a display device. In order to make purposes, technical solutions, and effects of the present application clearer and more specific, the present application is further described in detail below with reference to the accompanying drawings and examples. It should be understood that the specific embodiments described herein are only used to explain the application, and are not used to limit the present application.

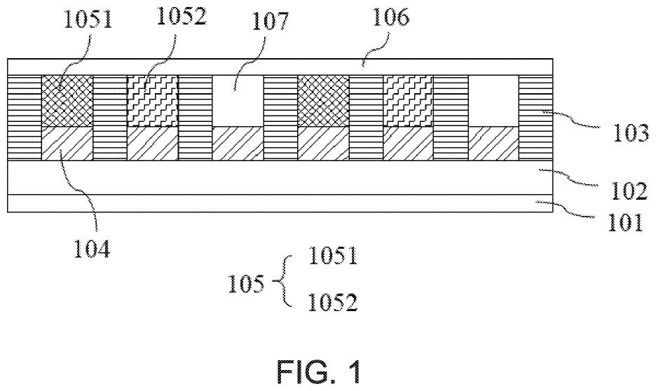

As shown in FIG. 1, which is a structural diagram of a display panel provided by an embodiment of the present application, components of the present application and relative positional relationships between the components can be seen intuitively. The display panel includes a first glass substrate 101, a thin-film transistor layer 102, black matrices 103, first color micro LEDs 104, a pixel layer 105, and a second glass substrate 106. The thin-film transistor layer 102 is disposed on the first glass substrate 101. The black matrices 103 are disposed on the thin-film transistor layer 102 and are arranged in an array. The first color micro LEDs 104 are disposed on the thin-film transistor layer 102 and are disposed between the black matrices 103. A height of each of the first color micro LEDs 104 is less than a height of each of the black matrices 103. The pixel layer 105 is disposed on the first color micro LEDs 104 and includes second color sub-pixels 1051 and third color sub-pixels 1052. The second glass substrate 106 is disposed on the black matrices 103 and the pixel layer 105.

It should be explained that, in this embodiment, the first color micro LEDs 104 are configured as a backlight source, and the pixel layer 105 is configured as a color filter layer. Combinations of the first color micro LEDs 104, the second color sub-pixels 1051, and the third color sub-pixels 1052 can realize a full-color display.

It should be explained that, in this embodiment, the black matrices 103 are disposed on the thin-film transistor layer 102, and the first color micro LEDs 104 are disposed between the black matrices 103. This can prevent that, in the prior art, the black matrices are formed after forming micro LEDs, and high temperature and alkaline developer in the yellow light process affect the micro LEDs and make them fail, thereby affecting overall display effects. Also, in this embodiment, the height of each of the black matrices 103 is configured to be greater than the height of each of the first color micro LEDs 104, and the pixel layer 105 is disposed on the first color micro LEDs 104. The black matrices 103 can not only can be configured as black matrices on two sides of the micro LEDs 104 to block light from a side of the micro LEDs 104 and prevent light between different micro LEDs from crosstalking, but can also be configured as a pixel defining layer of the pixel layer 105 to restrict a printing region and form shapes of the sub-pixels at a same time, as well as prevent different sub-pixels from crosstalking, which can simplify manufacturing processes.

In an embodiment, the first color micro LEDs 104 consist of blue micro LEDs. The second color sub-pixels 1051 and the third color sub-pixels 1052 respectively consist of red sub-pixels and green sub-pixels. In this embodiment, the blue micro LEDs excite the red sub-pixels and the green sub-pixels to obtain a color display effect. In another embodiment, the first color micro LEDs 104 can include red micro LEDs or green LEDs. Correspondingly, the second color sub-pixels 1051 and the third color sub-pixels 1052 respectively consist of green sub-pixels and blue sub-pixels; or the second color sub-pixels 1051 and the third color sub-pixels 1052 respectively consist of red sub-pixels and blue sub-pixels.

In an embodiment, each of the red sub-pixels and each of the green sub-pixels constitute a repeating unit, and repeating units are cyclically arranged at a pitch of a width of a sub-pixel. The pitch 107 is an empty region or filled with a transparent material, and missing blue sub-pixels (i.e., the pitch 107 in the figure) are provided by the blue micro LEDs.

In an embodiment, the red sub-pixels and the green sub-pixels are respectively made of a red quantum dot material and a green quantum dot material. Quantum dot technology is considered to be a core of next-generation display technology that can compete with OLEDs. Quantum dot materials have advantages of high luminous efficiency, high color purity, and wide color gamut. Using quantum dot materials as a color filter layer can provide more realistic color display for display panels. Embodiments of the present application combine the advantages of the micro LEDs and the quantum dots, which can make the display panel have the advantages of low power consumption, high performance, and long service life.

In an embodiment, a thickness of each of the black matrices 103 ranges from 10 to 12 microns. This embodiment adopts the black matrices with thick film thickness that can be configured as a barrier layer of the micro LEDs and a defining layer of the pixel layer. This simplifies the manufacturing processes and prevents that, in the prior art, the black matrices are formed after forming the micro LEDs, and high temperature and alkaline developer in the yellow light process affect the micro LEDs and make them fail, thereby affecting overall display effects.

In an embodiment, a thickness of the pixel layer 105 ranges from 5 to 7 microns. Specifically, a height of a normal micro LED ranges from 5 to 6 microns, and the height of each of the black matrices provided in this embodiment of the present application can range from 10 microns to 12 microns. Accordingly, the thickness of the pixel layer 105 ranges from 5 to 7 microns. If the pixel layer 105 is printed by the quantum dot materials, color purity, color saturation, and other indicators of the quantum dot materials in this thickness range can satisfy normal display requirements.

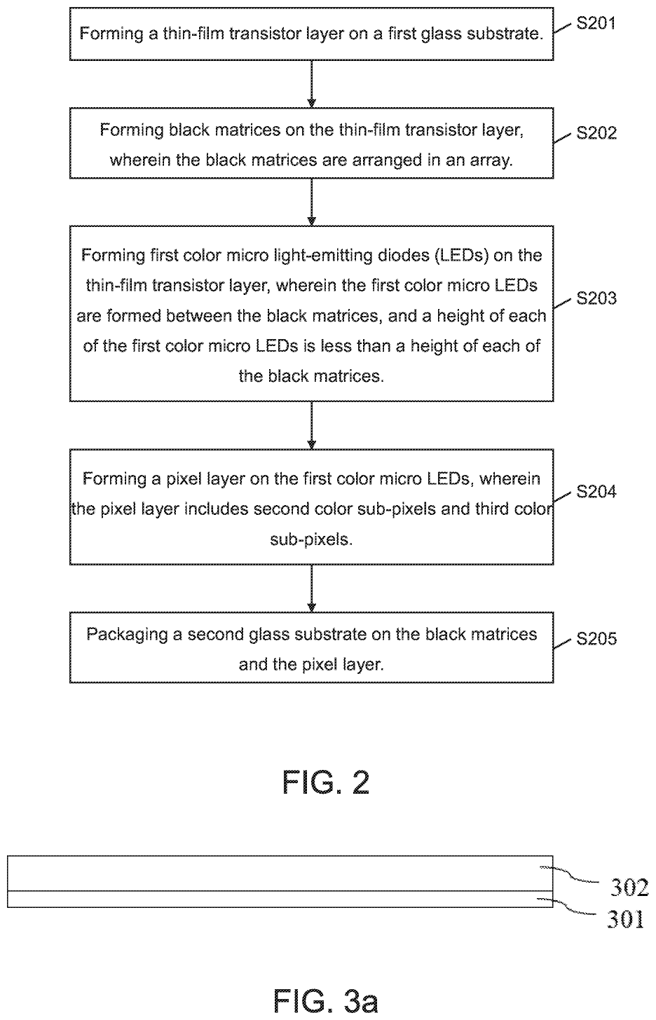

As shown in FIG. 2, a flowchart of a manufacturing method of the display panel provided by an embodiment of the present application includes the steps of:

S201, forming a thin-film transistor layer on a first glass substrate;

S202, forming black matrices on the thin-film transistor layer, wherein the black matrices are arranged in an array;

S203, forming first color micro light-emitting diodes (LEDs) on the thin-film transistor layer, wherein the first color micro LEDs are formed between the black matrices, and a height of each of the first color micro LEDs is less than a height of each of the black matrices;

S204, forming a pixel layer on the first color micro LEDs, wherein the pixel layer includes second color sub-pixels and third color sub-pixels; and

S205, packaging a second glass substrate on the black matrices and the pixel layer.

Specifically, in S201, the thin-film transistor layer formed on a clean and dry first glass substrate is configured as a driver for a first color micro LEDs chip. In S202, the black matrices are formed by a yellow light process, and the steps of forming the black matrices include photoresist coating, pre-baking, exposure, development, and post-baking. In S203, the first color micro LEDs chip formed on a substrate of the black matrices is configured as an excitation light source of the pixel layer. In S204, second color sub-pixels and third color sub-pixels printed by inkjet printing technology are configured as the second color sub-pixels and the third color sub-pixels in a color filter layer (first color sub-pixels are provided by the first color micro LEDs chip). In S205, an uppermost layer is packaged with the second glass substrate to obtain a final display panel.

It should be explained that there are an opposite-sides solution and a same-side solution for making such a structure using micro LEDs as a backlight source and the pixel layer as the color filter layer. For the opposite-sides solution, a micro LED backlight substrate and a pixel color filter substrate are aligned after they are formed. This solution has complicated processes and requires support of high-precision alignment equipment, and has limited resources. For the same-side solution, the color filter layer is formed on the micro LEDs. In an embodiment of the present application, the black matrices of the yellow light process are formed first, and then the micro LEDs chip is transferred, thereby preventing the micro LEDs chip from being damaged by the yellow light process, and simplifying processes. Moreover, it does not require alignment operation and reduces difficulty of production.

In an embodiment, the first color micro LEDs consist of blue micro LEDs. The second color sub-pixels and the third color sub-pixels respectively consist of red sub-pixels and green sub-pixels. In this embodiment, the blue micro LEDs excite the red sub-pixels and the green sub-pixels to obtain a color display effect. In another embodiment, the first color micro LEDs can include red micro LEDs or green LEDs. Correspondingly, the second color sub-pixels and the third color sub-pixels respectively consist of green sub-pixels and blue sub-pixels; or the second color sub-pixels and the third color sub-pixels respectively consist of red sub-pixels and blue sub-pixels.

In an embodiment, each of the red sub-pixels and each of the green sub-pixels constitute a repeating unit, and repeating units are cyclically arranged at a pitch of a width of a sub-pixel. The pitch is an empty region or filled with a transparent material, and missing blue sub-pixels are provided by the blue micro LEDs.

In an embodiment, the red sub-pixels and the green sub-pixels are respectively made of a red quantum dot material and a green quantum dot material.

In an embodiment, a thickness of each of the black matrices ranges from 10 to 12 microns.

In an embodiment, a thickness of the pixel layer 105 ranges from 5 to 7 microns. Specifically, a height of a normal micro LED ranges from 5 to 6 microns, and the height of each of the black matrices provided in this embodiment of the present application can range from 10 microns to 12 microns. Accordingly, the thickness of the pixel layer 105 ranges from 5 to 7 microns. If the pixel layer 105 is printed by the quantum dot materials, color purity, color saturation, and other indicators of the quantum dot materials in this thickness range can satisfy normal display requirements.

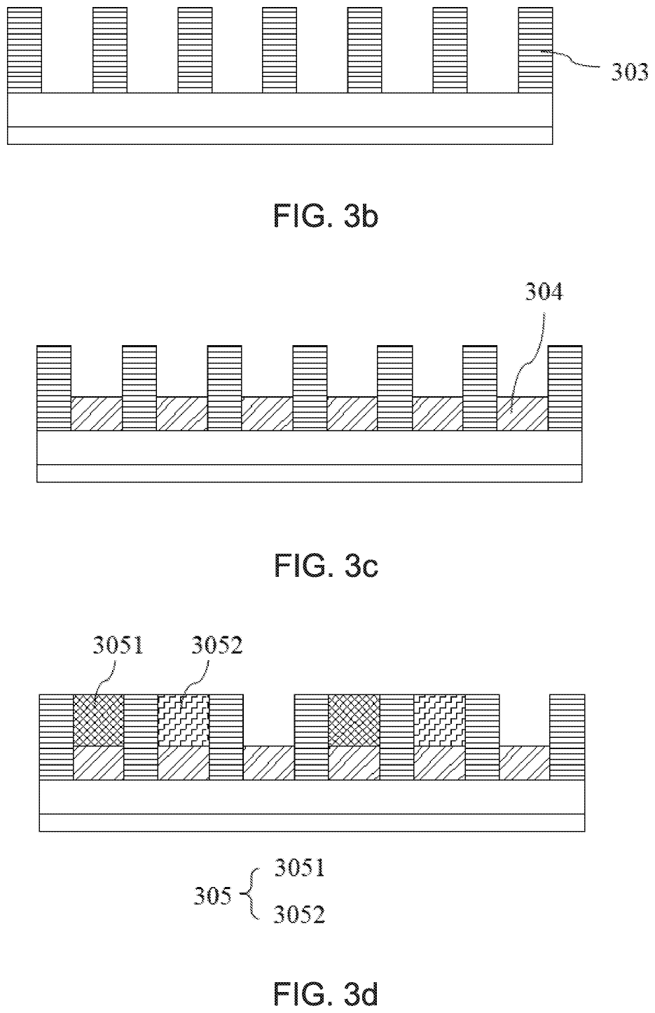

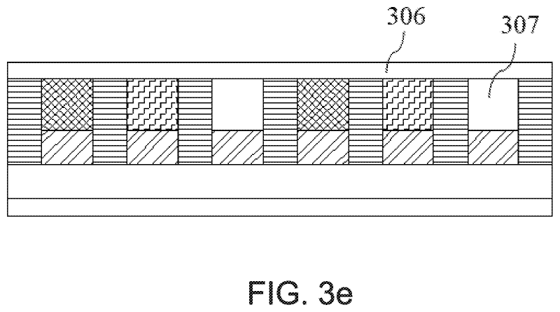

Please refer to FIGS. 3a to 3e, which are structural diagrams of manufacturing processes of the display panel provided by an embodiment of the present application. First, a thin-film transistor layer 302 is formed on a first glass substrate 301. For example, the thin-film transistor layer 302 includes a buffer layer (not shown), a semiconductor layer (not shown) disposed on the buffer layer, a gate insulating layer (not shown) disposed on the semiconductor layer, a gate (not shown) disposed on the gate insulating layer, an interlayer insulating layer (not shown) disposed on the gate, and a source (not shown) and a drain (not shown) disposed on the interlayer insulating layer. The source and the drain are respectively connected to two ends of the semiconductor layer by a first hole and a second hole. Second, black matrices 303 are formed on the thin-film transistor 302, and a height of each of the black matrices can range from 10 microns to 12 microns. Third, first color micro LEDs 304 are formed on the thin-film transistor layer 302 and are formed between the black matrices 303. A height of each of the first color micro LEDs 304 is less than the height of each of the black matrices 303. In this embodiment, the black matrices 303 are formed first, and then the first color micro LEDs 304 are formed, which prevents the micro LEDs from being affected by high temperature and alkaline developer in the yellow light process of forming the black matrices 303. Fourth, a pixel layer 305 is formed on the first color micro LEDs 304. The pixel layer 305 includes second color sub-pixels 3051 and third color sub-pixels 3052. Combinations of the first color micro LEDs 304, the second color sub-pixels 3051, and the third color sub-pixels 3052 can realize a full-color display. Lastly, a second glass substrate 306 is packaged on the black matrices 303 and the pixel layer 305 to obtain the display panel.

It should be explained that the steps of forming the black matrices 303 include photoresist coating, pre-baking, exposure, development, and post-baking. In this embodiment, the black matrices 303 are formed first, and then the first color micro LEDs 304 are formed, which prevents the micro LEDs from being affected by high temperature and alkaline developer in the yellow light process of forming the black matrices 303. This embodiment adopts the black matrices 303 with thick film thickness that can not only can be configured as black matrices on two sides of the micro LEDs 304 to block light from a side of the micro LEDs 304 and prevent light between different micro LEDs from crosstalking, but can also be configured as a pixel defining layer of the pixel layer 305 to restrict a printing region and form shapes of the sub-pixels at a same time, as well as prevent different sub-pixels from crosstalking.

In an embodiment, the first color micro LEDs 304 consist of blue micro LEDs. The second color sub-pixels 3051 and the third color sub-pixels 3052 respectively consist of red sub-pixels and green sub-pixels. In this embodiment, the blue micro LEDs excite the red sub-pixels and the green sub-pixels to obtain a color display effect. In another embodiment, the first color micro LEDs 304 can include red micro LEDs or green LEDs. Correspondingly, the second color sub-pixels 3051 and the third color sub-pixels 3052 respectively consist of green sub-pixels and blue sub-pixels; or the second color sub-pixels 3051 and the third color sub-pixels 3052 respectively consist of red sub-pixels and blue sub-pixels.

In an embodiment, each of the red sub-pixels and each of the green sub-pixels constitute a repeating unit, and repeating units are cyclically arranged at a pitch of a width of a sub-pixel. The pitch 307 is an empty region or filled with a transparent material, and missing blue sub-pixels (i.e., the pitch 307 in the figure) are provided by the blue micro LEDs.

In an embodiment, the red sub-pixels and the green sub-pixels are respectively made of a red quantum dot material and a green quantum dot material.

A display device provided by an embodiment of the present application includes a driving chip and the display panel described above. The display device provided by an embodiment of the present application can be any product or component having a display function, such as a mobile phone, a tablet computer, a television, a display, a laptop computer, a digital camera, a navigator, and the like.

In summary, the display panel provided by an embodiment of the present application disposes the black matrices as a barrier between adjacent micro LEDs and adjacent sub-pixels. The black matrices with thick film thickness can be configured as black matrices on two sides of the micro LEDs, which block light from a side of the micro LEDs and prevent light between different micro LEDs from crosstalking. Moreover, they can be configured as a pixel defining layer of the pixel layer, restricting a printing region and forming shapes of the sub-pixels at a same time, while preventing different sub-pixels from crosstalking. This not only simplifies manufacturing processes, but also greatly improves contrast of the display panel. This solves technical problems in the prior art that high temperature and alkaline developer in the yellow light process for forming the black matrices on the micro LEDs affect the micro LEDs and make them fail, thereby affecting overall display effects.

Understandably, those having ordinary skills of the art may easily contemplate various changes and modifications of the technical solution and technical ideas of the present application and all these changes and modifications are considered within the protection scope of right for the present application.

What is claimed is:

1. A display panel, comprising:
a first glass substrate;
a thin-film transistor layer disposed on the first glass substrate;
black matrices disposed on the thin-film transistor layer and arranged in an array;
first color micro light-emitting diodes (LEDs) disposed on the thin-film transistor layer and disposed between the black matrices, wherein a height of each of the first color micro LEDs is less than a height of each of the black matrices;
a pixel layer disposed on the first color micro LEDs and comprising second color sub-pixels and third color sub-pixels; and
a second glass substrate disposed on the black matrices and the pixel layer.

2. The display panel as claimed in claim 1, wherein the first color micro LEDs consist of blue micro LEDs, and the second color sub-pixels and the third color sub-pixels respectively consist of red sub-pixels and green sub-pixels.

3. The display panel as claimed in claim 2, wherein each of the red sub-pixels and each of the green sub-pixels constitute a repeating unit, and repeating units are cyclically arranged at a pitch of a width of a sub-pixel.

4. The display panel as claimed in claim 2, wherein the red sub-pixels and the green sub-pixels are respectively made of a red quantum dot material and a green quantum dot material.

5. The display panel as claimed in claim 1, wherein a thickness of each of the black matrices ranges from 10 to 12 microns.

6. The display panel as claimed in claim 1, wherein a thickness of the pixel layer ranges from 5 to 7 microns.

7. A manufacturing method of a display panel, comprising the steps of:
forming a thin-film transistor layer on a first glass substrate;
forming black matrices on the thin-film transistor layer, wherein the black matrices are arranged in an array;
forming first color micro light-emitting diodes (LEDs) on the thin-film transistor layer, wherein the first color micro LEDs are formed between the black matrices, and a height of each of the first color micro LEDs is less than a height of each of the black matrices;
forming a pixel layer on the first color micro LEDs, wherein the pixel layer comprises second color sub-pixels and third color sub-pixels; and
packaging a second glass substrate on the black matrices and the pixel layer.

8. The manufacturing method of the display panel as claimed in claim 7, wherein the first color micro LEDs consist of blue micro LEDs, and the second color sub-pixels and the third color sub-pixels respectively consist of red sub-pixels and green sub-pixels.

9. The manufacturing method of the display panel as claimed in claim 8, wherein the red sub-pixels and the green sub-pixels are respectively made of a red quantum dot material and a green quantum dot material.

10. The manufacturing method of the display panel as claimed in claim 7, wherein a thickness of each of the black matrices ranges from 10 to 12 microns.

11. The manufacturing method of the display panel as claimed in claim 7, wherein a thickness of the pixel layer ranges from 5 to 7 microns.

12. A display device, comprising a driving chip and a display panel, wherein the display panel comprises:
a first glass substrate;
a thin-film transistor layer disposed on the first glass substrate;
black matrices disposed on the thin-film transistor layer and arranged in an array;
first color micro light-emitting diodes (LEDs) disposed on the thin-film transistor layer and disposed between the black matrices, wherein a height of each of the first color micro LEDs is less than a height of each of the black matrices;
a pixel layer disposed on the first color micro LEDs and comprising second color sub-pixels and third color sub-pixels; and
a second glass substrate disposed on the black matrices and the pixel layer.

13. The display device as claimed in claim 12, wherein the first color micro LEDs consist of blue micro LEDs, and the second color sub-pixels and the third color sub-pixels respectively consist of red sub-pixels and green sub-pixels.

14. The display device as claimed in claim 13, wherein each of the red sub-pixels and each of the green sub-pixels constitute a repeating unit, and repeating units are cyclically arranged at a pitch of a width of a sub-pixel.

15. The display device as claimed in claim 13, wherein the red sub-pixels and the green sub-pixels are respectively made of a red quantum dot material and a green quantum dot material.

16. The display device as claimed in claim 12, wherein a thickness of each of the black matrices ranges from 10 to 12 microns.

17. The display device as claimed in claim 12, wherein a thickness of the pixel layer ranges from 5 to 7 microns.
